(19) United States
(12) Patent Application Publication
(10) Pub. No.: US 2022/0403528 A1
(43) Pub. Date: Dec. 22, 2022

(54) COATED METAL ALLOY SUBSTRATE AND PROCESS FOR PRODUCTION THEREOF

(71) Applicant: HEWLETT-PACKARD DEVELOPMENT COMPANY, L.P., SPRING, TX (US)

(72) Inventors: KUAN-TING WU, TAIPEI CITY (TW); CHI HAO CHANG, TAIPEI CITY (TW); QINGYONG GUO, SHANGHAI (CN)

(21) Appl. No.: 17/777,745

(22) PCT Filed: Dec. 9, 2019
(86) PCT No.: PCT/CN2019/123982

§ 371 Date: May 18, 2022

(51) Int. Cl. C23C 28/00; C23C 22/48; C23C 22/78; C25D 11/30; C25D 11/02; C25D 13/12; C25D 13/20; C25D 13/22; C09D 5/44; C09D 5/02; C09D 133/04; C09D 7/20; H05K 5/04; G06F 1/16

(52) U.S. Cl. CPC C23C 28/00; C23C 22/48; C23C 22/78; C25D 11/30; C25D 11/026; C25D 13/12; C25D 13/20; C25D 13/22; C09D 5/4473; C09D 5/448; C09D 5/021; C09D 133/04; C09D 7/20; H05K 5/04; G06F 1/1613

(57) ABSTRACT

A coated metal alloy substrate for an electronic device, a process for producing a coated metal alloy substrate for an electronic device and a housing for an electronic device, comprising a coated metal alloy substrate wherein the coated metal alloy CA substrate comprises at least one chamfered edge (1) and comprises: a passivation layer (2) deposited on the at least one chamfered edge (1); an electrophoretic deposition layer (3) deposited on the passivation layer (2); and a hydrophobic layer (4) deposited on the electrophoretic deposition layer (3).

Electronic devices, such as laptops and mobile phones, include various components located within a metal alloy housing. Such metal alloy housings are made of metal alloy substrates that provide sought after metallic lustre of the metal alloy enclosure. Such enclosures should be able to withstand wear and tear from regular use and exposure to the natural environment.

### BRIEF DESCRIPTION OF THE FIGURES

FIG. 1 is a flowchart showing an example of a process for producing a coated metal alloy substrate for an electronic device.

FIG. 2 is a partial cross-sectional diagram showing an example of a coated metal substrate.

FIG. 3 is a flowchart showing an example of a process for producing a coated metal alloy substrate.

FIG. 4 is a partial cross-sectional diagram showing an example of a coated metal substrate comprising the formation of a first layered surface.

FIG. 5 is a flowchart as an example of a process for producing a coated metal alloy substrate for an electronic device.

FIG. 6 is a partial cross-sectional diagram showing a coated metal substrate with at least one chamfered edge.

FIG. 7 shows an example housing for a laptop.

The figures depict several examples of the present disclosure. It should be understood that the present disclosure is not limited to the examples depicted in the figures.

### DETAILED DESCRIPTION

Before the coated metal alloy substrate, process for producing a coated metal alloy substrate, and electronic device with a housing comprising a coated metal alloy substrate are disclosed and described, it is to be understood that this disclosure is not limited to the particular process details and materials disclosed herein because such process details and materials may vary somewhat. It is also to be understood that the terminology used herein is used for the purpose of describing particular examples. The terms are not intended to be limiting because the scope of the present disclosure is intended to be limited by the appended claims and equivalents thereof.

It is noted that, as used in this specification and the appended claims, the singular forms “a”, “an” and “the” include plural referents unless the context clearly dictates otherwise.

If a standard test is mentioned herein, unless otherwise stated, the version of the test to be referred to is the most recent at the time of filing this patent application.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

Concentrations, amounts, and other numerical data may be expressed or presented herein in a range format. It is to be understood that such a range format is used merely for convenience and brevity and thus should be interpreted flexibly to include the numerical values explicitly recited as the limits of the range and also to include all the individual numerical values or sub-ranges encompassed within that range as if each numerical value and sub-range is explicitly recited. As an illustration, a numerical range of “about 1 wt. % to about 5 wt. %” should be interpreted to include the explicitly recited values of about 1 wt. % to about 5 wt. % and also include individual values and subranges within the indicated range. Thus, included in this numerical range are individual values such as 2, 3.5, and 4 and sub-ranges such as from 1-3, from 2-4, and from 3-5, etc. This same principle applies to ranges reciting a single numerical value. Furthermore, such an interpretation should apply regardless of the breadth of the range or the characteristics being described.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list based on their presentation in a common group without indications to the contrary.

As used herein, the term “deposited” when used to refer to the location or position of a layer includes the term “disposed” or “coated”.

As used herein, the term “engraving” when used to refer to the formation of a chamfered edge includes the term “etching” or “cutting”.

As used herein, the term “hydrophobic” refers to a physical property of a molecule, wherein the molecule has a low affinity towards water.

As used herein, the term “chamfered edge” refers to any edge of a substrate that has resulted from engraving or cutting.

As used herein, the term “non-chamfered surface” refers to any part of the substrate that has not been engraved or cut.

As used herein, the term “Log P” refers to the logarithm of the partition coefficient, abbreviated P. Log P is a measure of the hydrophobicity or hydrophillicity of a chemical substance. For example, components with a Log P of greater than 5 are considered to be hydrophobic compounds. Log P may be defined as the ratio of the concentrations of a solute in a biphasic system of n-octanol and water at equilibrium and at 25° C. and standard pressure. The Log P can be determined by calculation, for example, using a fragment-based and/or atom-based approach, for example, using Cambridge Soft software such as ChemDraw Ultra 12.0.

As used herein, the term “contact angle” refers to the angle measured through the liquid, where a liquid-vapour interface meets a solid surface. It quantifies the wettability of a solid surface by a liquid via the Young equation. A given system of solid, liquid, and vapour at a given temperature and pressure has a unique equilibrium contact angle. However, in practice a dynamic phenomenon of contact angle hysteresis is often observed, ranging from the advancing (maximal) contact angle to the receding (minimal) contact angle. The equilibrium contact is within the maximal and minimal values, and can be calculated from the minimal and maximal values. The equilibrium contact angle reflects the relative strength of the liquid, solid, and vapor molecular interaction. The contact angle may be measured using a Drop Shape Analyzer, such as DSA100.

As used herein, the term “comprises” has an open meaning, which allows other, unspecified features to be present. This term embraces, but is not limited to, the semi-closed term “consisting essentially of” and the closed term “consisting of”. Unless the context indicates otherwise, the term “comprises” may be replaced with either “consisting essentially of” or “consists of”.

Unless otherwise stated, any feature described herein can be combined with any other feature described herein.

The present inventors have found that it can be difficult to maintain a natural metallic lustre and a high gloss effect of metal alloy substrates. In particular, the present inventors have found that it can be difficult to fabricate metallic lustre effect at the chamfered edges of a metal alloy substrate when used at, for example, the click pad, the fingerprint scanner, the side wall and the logo of housings for electrical devices. The present inventors have found that the coated metal alloy substrates with one or more chamfered edges described herein can result in surfaces with good metallic lustre appearance, good corrosion resistance and/or a durable coating. The use of a passivation layer and an electrophoretic deposition layer applied to the chamfered edge(s) can allow colour to be added to the chamfered section via the electrophoretic deposition layer. Chamfered edges in different sections of the metal alloy substrate may be treated with electrophoretic deposition layers with different colours or different gloss levels allowing for a highly flexible design solution for chamfered metal alloys. The application of a hydrophobic layer has in some examples been seen to maintain the aesthetic properties and gloss at the chamfered edge, while also enhancing corrosion resistance.

### Coated Metal Alloy Substrate

In some examples there is provided a coated metal alloy substrate for an electronic device, wherein the coated metal alloy substrate comprises at least one chamfered edge and comprises:

a passivation layer deposited on the at least one chamfered edge;
an electrophoretic deposition layer deposited on the passivation layer; and
a hydrophobic layer deposited on the electrophoretic deposition layer.

### Metal Alloy Substrate

The metal alloy substrate may comprise a metal selected from aluminium, magnesium, lithium, titanium, niobium, zinc and alloys thereof. In some examples, the metal alloy substrate may comprise a metal alloy selected from an aluminium alloy, a magnesium alloy, a lithium alloy, a titanium alloy and stainless steel. These metals may be light-weight and can provide a durable housing.

Generally, the metal alloy comprises a content of metal of at least about 75 wt. %. For example, when the metal alloy is a magnesium alloy, the magnesium alloy may comprise at least about 80 wt. % magnesium, or at least 85 wt. % magnesium, or at least about 90 wt. % of magnesium, based on the total weight of the metal alloy.

The magnesium alloy may further comprise aluminium, zinc, manganese, silicon, copper, a rare earth metal or zirconium. The aluminium content may be about 2.5 wt. % to about 13.0 wt. %. When the magnesium alloy comprises aluminium, then at least one of manganese, zirconium, or silicon is also present. Examples of magnesium alloys include AZ31B, AZ61, AZ60, AZ80, AM60, AZ91D, LZ91, LZ14, ALZ691 alloys according to the American Society for Testing Materials standards.

In one example, the metal alloy comprises the components, based on the total weight of the metal alloy, Al: 0.02 wt. % to 9.7 wt. %, Zn: 0.02 wt. % to 1.4 wt. %, Mn: 0.02 wt. % to 0.5 wt. %, one or more component selected from Si: 0.02 wt. % to 0.1 wt. %, Fe: 0.004 wt. % to 0.05 wt. %, Ca: 0.0013 wt. % to 0.04 wt. %, Ni: 0.001 wt. % to 0.005 wt. %, Cu: 0.008 wt. % to 0.05 wt. %, Li: 9.0 wt. % to 14.3 wt. %, Zr: up to 0.002 wt. % and the balance being Mg and inevitable impurities.

In some examples, the metal alloy substrate may be an insert molded metal substrate to form a metal substrate with sections comprising a further material, such as plastics. For some examples, the metal alloy substrate is an insert moulded metal substrate comprising a plastic insert. The insert molded metal substrate may be formed by using the metal substrate as a mold. This metal mold may have a section into which a material, such as plastic, is injected to form the plastic insert. Plastics used for insert molded metal substrates may be selected from polybutylene terephthalate (PBT), polyphenylene sulfide (PPS), polyamide (nylon), polyphthalamide (PPA), acrylonitrile butadiene styrene (ABS), polyetheretherketone (PEEK), polycarbonate (PC) and acrylonitrile butadiene styrene with polycarbonate (ABS/PC) with 15 to 50 wt. % glass fibre filler.

In some examples, the metal alloy substrate has been pre-treated to form a first layered surface, as described herein. In some examples, the metal alloy substrate has been pre-treated to form a first treated surface, as described herein.

### Chamfered Edge

The metal alloy substrate comprises one chamfered edge or more than one chamfered edge. The one or more chamfered edges are formed by engraving the metal alloy substrate. The engraving process to form a chamfered edge can be carried out using a range of techniques including a computer numeric control (CNC)diamond cutter or a laser engraver. The engraving process exposes a non-oxidized surface of the substrate. The non-oxidized surface of the substrate exposed in this way is an uncoated surface of the substrate that has not undergone substantial oxidation, so that, for example, it retains its metallic appearance.

By coating the non-oxidised surface of the metal alloy substrate formed by engraving with a passivation layer, an electrophoretic deposition layer and a hydrophobic layer, it may be possible to both protect and retain the attractive, shiny appearance of the underlying metallic substrate.

### Passivation Layer

The passivation layer is deposited on the at least one chamfered edge. The passivation layer may be transparent. The passivation layer may comprise a chelating agent and a metal ion or chelated metal complex thereof, or a mixture of the chelating agent, the metal ion and the chelated metal complex. The chelated metal complex comprises a ligand coordinated to the metal ion. The ligand is the chelating agent.

The chelating agent may be selected from ethylenediaminetetraacetic acid (EDTA), ethylenediamine (EN), nitrilotriacetic acid (NTA), diethylenetriaminepenta(methylenephosphonic acid) (DTPPH), nitrilotris(methylenephosphonic acid) (NTMP), 1-hydroxyethane-1,1-diphosphonic acid (HEDP) and phosphoric acid. In one example, the chelating agent is DTPPH.

The metal ion is selected from an aluminium ion, a nickel ion, a chromium ion, a tin ion, an indium ion, and a zinc ion. In one example, the metal ion is selected from an aluminium ion, a nickel ion and a zinc ion.

In one example, the chelated metal complex may comprise DTPPH chelated to an aluminium ion. In another example, the chelated metal complex may comprise DTPPH chelated to a nickel ion. In a further example, the chelated metal complex may comprise DTPPH chelated to a zinc ion.

The passivation layer may have a thickness of from about 30 nm to about 3 μm, such as from about 200 nm to about 2 μm, or from about 500 nm to about 1 μm. The thickness of the layer can be measured after it has been applied using, for example, a micrometre screw gauge or scanning electron microscope (SEM).

### Electrophoretic Deposition Layer

The electrophoretic deposition layer is deposited on the passivation layer. In some examples, the electrophoretic deposition layer comprises an electrophoretic polymer. In some examples, the electrophoretic polymer may be selected from polyacrylic polymer, polyacrylamide-acrylic copolymer and epoxy-containing polymer.

The electrophoretic deposition layer may be transparent. In one example, the electrophoretic deposition layer is colourless. In another example, the electrophoretic polymer layer may comprise a colorant.

A “colorant” may be a material that imparts a colour to the electrophoretic deposition layer. As used herein, “colorant” includes pigments and dyes, such as those that impart colours, such as black, magenta, cyan, yellow and white to an electrophoretic deposition layer. The pigment particles may be dispersed throughout the electrophoretic deposition layer. The pigment may be selected from carbon black, titanium dioxide, clay, mica, talc, barium sulfate, calcium carbonate, synthetic pigment, pearl pigment, metallic powder, aluminium oxide, dye, graphene, graphite, pigment colorants, magnetic particles and an inorganic powder. Although the present description primarily exemplifies the use of pigment colorants, the term “pigment” can be used more generally to describe pigment colorants and also other pigments such as organometallics, ferrites and ceramics. In one example, the pigment is a dye. The dye may be dispersed throughout the electrophoretic deposition layer.

The colorant can be any colorant compatible with the electrophoretic polymer and useful for providing an electrophoretic deposition layer. For example, the colorant may be present as pigment particles, or may comprise a resin and a pigment. The pigments can be any of those standardly used in the art. In some examples, the colorant is selected from a cyan pigment, a magenta pigment, a yellow pigment and a black pigment. For example, pigments by Hoechst including Permanent Yellow DHG, Permanent Yellow GR, Permanent Yellow G, Permanent Yellow NCG-71, Permanent Yellow GG, Hansa Yellow RA, Hansa Brilliant Yellow 5GX-02, Hansa Yellow X, NOVAPERM® YELLOW HR, NOVAPERM® YELLOW FGL, Hansa Brilliant Yellow 10GX, Permanent Yellow G3R-01, HOSTAPERM® YELLOW H4G, HOSTAPERM® YELLOW H3G, HOSTAPERM® ORANGE GR, HOSTAPERM® SCARLET GO, Permanent Rubine F6B; pigments by Sun Chemical including L74-1357 Yellow, L75-1331 Yellow, L75-2337 Yellow; pigments by Heubach including DALAMAR® YELLOW YT-858-D; pigments by Ciba-Geigy including CROMOPHTHAL® YELLOW 3 G, CROMOPHTHAL® YELLOW GR, CROMOPHTHAL®YELLOW 8 G, IRGAZINE® YELLOW 5GT, IRGALITE® RUBINE 4BL, MONASTRAL® MAGENTA, MONASTRAL® SCARLET, MONASTRAL® VIOLET, MONASTRAL® RED, MONASTRAL® VIOLET; pigments by BASF including LUMOGEN® LIGHT YELLOW, PALIOGEN® ORANGE, HELIOGEN® BLUE L 690 IF, HELIOGEN® BLUE TBD 7010, HELIOGEN® BLUE K 7090, HELIOGEN® BLUE L 710 IF, HELIOGEN® BLUE L 6470, HELIOGEN® GREEN K 8683, HELIOGEN® GREEN L 9140; pigments by Mobay including QUINDO® MAGENTA, INDOFAST® BRILLIANT SCARLET, QUINDO® RED 6700, QUINDO® RED 6713, INDOFAST® VIOLET; pigments by Cabot including Maroon B STERLING® NS BLACK, STERLING® NSX 76, MOGUL® L; pigments by DuPont including TIPURE® R-101; and pigments by Paul Uhlich including UHLICH® BK 8200. If the pigment is a white pigment particle, the pigment particle may be selected from TiO₂, calcium carbonate, zinc oxide, and mixtures thereof. In some examples, the white pigment particle may comprise an alumina-TiO₂ pigment. In some examples the colorant may be Pacific Blue dye.

The colorant or pigment may be present in the electrophoretic deposition layer in an amount of from about 0.1 wt. % to about 15 wt. %, based on the total weight of the electrophoretic deposition layer. For example, the colorant or pigment may be present in the electrophoretic deposition layer in an amount from about 0.5 wt. % to about 13 wt. %, or from about 1 wt. % to about 12 wt. %, or from about 1.5 wt. % to about 10 wt. %, or from about 2 wt. % to about 9 wt. %, or from about 2.5 wt. % to about 8 wt. %, or from about 3 wt. % to about 7 wt. %, or from about 3.5 wt. % to about 6 wt. %, or from about 4 wt. % to about 5 wt. %, based on the total weight of the electrophoretic deposition layer. In some examples, the colorant or pigment particle may be present in the electrophoretic deposition layer in an amount of at least 5.5 wt. % based on the total weight of the electrophoretic deposition layer, for example at least 4.5 wt. % based on the total weight of the electrophoretic deposition layer.

In one example, the electrophoretic deposition layer comprises, based on the total weight of the electrophoretic deposition layer, 10 wt. % polyacrylic copolymer resin, 0.1 wt. % Pacific Blue dye, 0.3 wt. % of an anionic surfactant, such as sodium dodecylbenzene and 89.6 wt. % de-ionized water.

In some examples, the electrophoretic deposition layer comprises at least a first and second portion, wherein the first and second portion comprise a different colorant.

The electrophoretic deposition layer may have a thickness of from about 5 μm to about 60 μm, for example from about 10 μm to about 55 μm, or from about 15 μm to about 50 μm, or from about 20 μm to about 45 μm, or from about 25 μm to about 40 μm, or from about 30 μm to about 35 μm. The thickness of the layer can be measured after it has been applied using, for example, a micrometre screw gauge or scanning electron microscope (SEM).

The presence of a passivation layer and an electrophoretic deposition layer may protect and retain the attractive and shiny appearance of the underlying metallic substrate.

### Sealing Layer

In some examples, the metal alloy substrate further comprises a sealing layer deposited between the passivation layer and the electrophoretic deposition layer.

In some examples, the sealing layer comprises a metal compound and a surfactant. In some examples, the metal compound may comprise a cation selected from aluminium, nickel or cerium. In some examples, the metal compound may comprise an anion selected from fluoride or acetate. In some examples, the metal compound is selected from aluminium fluoride, nickel fluoride, cerium fluoride, cerium acetate, aluminium acetate, nickel acetate or a combination thereof. In some examples, the metal compound may be present in an amount from about 0.5 wt % to about 5.0 wt %, or from about 0.75 to about 4.0 wt %, or from about 1.0 wt % to about 3.5 wt % by weight of the sealing layer.

In some examples, the surfactant is an anionic surfactant. In some examples, the surfactant may be selected from alcohol sulfates, alkylbenzene sulfonates, sodium caseinate, sodium polyacrylate, sodium polyoxyethylene alkyl ether carboxylate, sodium dodecyl sulfate or a combination thereof. The surfactant may be present in an amount from about 0.1 wt % to about 2 wt %, or from about 0.3 wt % to about 1.75 wt %, or about 0.5 wt % to about 1.5 wt % by weight of the sealing layer.

In some examples, after applying the sealing layer, the sealing layer is heated. In some examples, the sealing layer is heated to a temperature from about 25° C. to about 100° C. In some examples, the sealing layer is heated to a temperature greater than about 25° C., or greater than 30° C., or greater than about 40° C., or greater than about 50° C., or greater than about 60° C., or greater than about 70° C., or greater than about 80° C., than about 90° C.

In some examples, the sealing layer may have a thickness of from about 1 μm to about 3 μm. The thickness of the layer can be measured after it has been applied using, for example, a micrometre screw gauge or scanning electron microscope (SEM).

### Hydrophobic Layer

The hydrophobic layer is deposited on the electrophoretic deposition layer. In some examples, the hydrophobic layer is transparent. The hydrophobic layer may have a high contact angle. In one example, the hydrophobic layer may have a contact angle of about 100° or more, such about 105° or more, or about 110° or more.

The hydrophobic layer may comprise a hydrophobic polymer, for example, which comprises 7-carbons or more. The hydrophobic polymer may have a Log P of greater than about 2, or greater than about 2.5, or greater than about 3, or greater than about 3.5, or greater than about 4, or greater than about 4.5, or greater than about 5. The hydrophobic polymer may have a solubility of less than 50 mg/ml in water at 25° C., or less than 25 mg/ml in water at 25° C., or less than 10 mg/ml in water at 25° C.

In some examples, the hydrophobic layer may comprise a fluoropolymer. The fluoropolymer may be selected from fluorinated olefin-based polymers, fluoroacrylates, fluorosilicone acrylates, fluorourethanes, perfluoropolyethers, perfluoropolyoxetanes, C1 to C6 fluorotelomers, polytetrafluoroethylene, polyvinylidenefluoride and fluorosiloxane. In one example, the fluoropolymer is polyvinylidenefluoride.

The fluoropolymer comprised in the hydrophobic layer may be a UV polymer, which may be cured at 80 to 120° C. The fluoropolymer comprised in the hydrophobic layer may be a hydrophobic polymer, comprising 7-carbons or more. The fluoropolymer may have a weight average molecular weight from about 25,000 to about 100,000.

The hydrophobic layer may comprise at least 20 wt. % of a fluoropolymer, based on the total weight of the hydrophobic layer. For example, the hydrophobic layer may comprise at least 25 wt. % of fluoropolymer, or at least 30 wt. % of fluoropolymer, or at least 40 wt.-% of fluoropolymer, or at least 50 wt.-% of fluoropolymer, or at least 60 wt.-% of fluoropolymer, or at least 70 wt.-% of fluoropolymer, based on the total weight of the hydrophobic layer.

In some examples, the hydrophobic layer may comprise a long chain silane polymer. A long chain silane polymer herein may refer to any alkyl-substituted silane polymer with an alkyl chain of at least 6 carbons, or at least 7 carbons, or at least 8 carbons, or at least 9 carbons, or at least 10 carbons, or at least 11 carbons. The long chain silane polymer may be selected from dodecyltrimethoxysilane, mecaptoundecyltrimethoxysilane, triethoxysilylundecanal, 11-aminoundecyltriethoxysilane, and N-(2-aminoethyl)-11-undecyltrimethoxysilane or a combination thereof.

In some examples, the hydrophobic layer may comprise at least 20 wt. % of a long chain silane polymer based on the total weigh of the hydrophobic layer. For example, the hydrophobic layer may comprise at least 25 wt. % of a long chain silane polymer, or at least 30 wt. %, or at least 40 wt. % of at least 50 wt. %, or at least 60 wt. %, or at least 70 wt. % of a long chain silane polymer, based on the total weight of the hydrophobic layer.

In addition to the hydrophobic polymer, the hydrophobic layer may further comprise an acrylic resin. In some examples, the hydrophobic layer may comprise at least 25 wt. % of acrylic resin, or at least 30 wt. % of acrylic resin, or at least 40 wt. % of acrylic resin, or at least 50 wt.-% of acrylic resin, or at least 60 wt.-% of acrylic resin, or at least 70 wt. % of acrylic resin, based on the total weight of the hydrophobic layer. In some examples, the acrylic resin may be formed from at least one monomer selected from methyl methacrylate, ethyl acrylate, butyl acrylate or a combination thereof. In some examples, the acrylic resin is a methyl methacrylate ethyl acrylate copolymer.

In some examples, the acrylic resin may have a weight average molecular weight from about 80,000 to about 200,000, or from about 100,000 to about 180,000, or from about 125,000 to about 155,000. In some examples, the acrylic resin may have a weight average molecular weight greater than 80,000, or greater than 100,000, or greater than 120,000. In some examples, the acrylic resin may have a weight average molecular weight less than 250,000, or less than 200,000 or less than 180,000.

In some examples, the acrylic resin may have a glass transition temperature (T_{g}) of greater than about 50° C., or greater than about 55° C. In some examples, the acrylic resin may have a glass transition temperature (T_{g}) of less than about 100° C., or less than about 90° C., or less than about 80° C., or less than about 70° C. In some examples, the acrylic resin may have a glass transition temperature (T_{g}) of about 60° C. The method of measuring the glass transition temperature (T_{g}) parameter is described in, for example, Polymer Handbook, 3^{rd} Edition, authored by J. Brandrup, edited by E. H. Immergut, Wiley-Interscience.

In some examples, the hydrophobic layer is formed by applying a fluid comprising a fluoropolymer, an acrylic resin and at least one solvent. In some examples, the solvent is isophorone, cyclohexanone or a combination thereof. In some examples, the fluid comprises 20 wt. % polyvinylidenefluoride, 40 wt. % isophorone, 5 wt. % cyclohexanone and 35 wt. % acrylic resin, based on the total weight of the fluid. In some examples, the hydrophobic layer is heated after applying the hydrophobic fluid. In some examples, the hydrophobic layer is heated to a temperature of at least about 80° C., or at least about 90° C., or at least about 100° C., or at least about 110° C. In some examples, the hydrophobic layer is heated to a temperature from about 80° C. to about 120° C.

The hydrophobic layer may have a thickness of about from 10 nm to about 1 μm, such as from about 50 nm to about 900 nm, or from about 100 nm to about 800 nm, or from about 200 nm to about 700 nm, or from about 300 nm to about 600 nm, or from about 400 nm to about 700 nm. The thickness of the layer can be measured after it has been applied using, for example, a scanning electron microscope (SEM).

In one example, the hydrophobic layer may be applied to the entire metal alloy substrate, for example, the hydrophobic layer is applied to the electrophoretic deposition layer both at the chamfered edge and the non-chamfered surface.

The hydrophobic layer may help to maintain the metallic lustre at the chamfered edge. The hydrophobic layer may enhance corrosion resistance at the chamfered edge. The hydrophobic layer may have an anti-smudge function and provide a smooth touch feeling. The hydrophobic layer may have good water resistance and may be easily cleaned.

### Process for Producing a Coated Metal Alloy Substrate

The present disclosure also relates to a process for producing a coated metal alloy substrate disclosed herein.

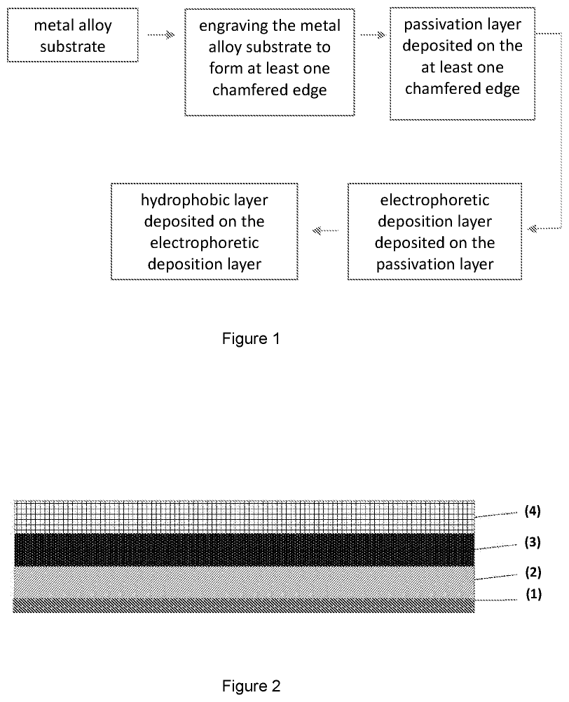

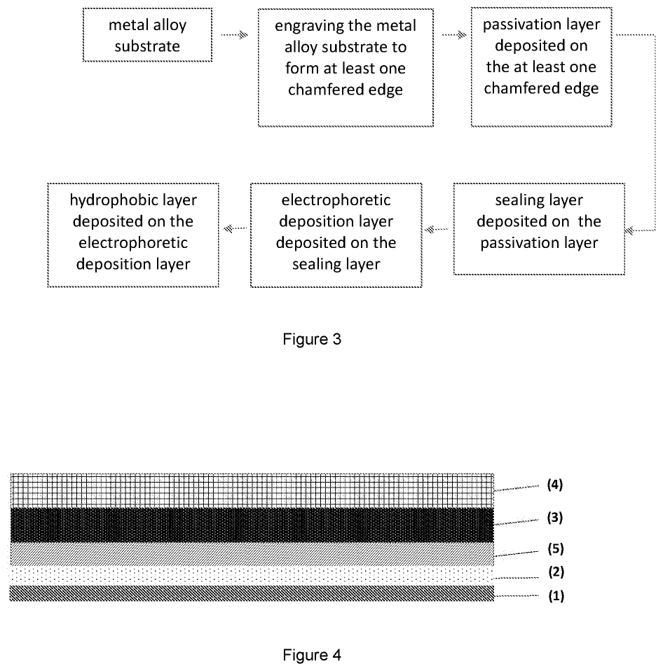

The process for producing a coated metal alloy is described below and shown in the flow chart in FIG. 1.

In some examples there is provided a process for producing a coated metal alloy substrate for an electronic device comprising:

engraving the metal alloy substrate to form at least one chamfered edge;
applying a passivation layer to the at least one chamfered edge;
applying an electrophoretic deposition layer to the passivation layer; and
applying a hydrophobic layer to the electrophoretic deposition layer.

In some examples, the process may be repeated any number of times. In other words, after applying a hydrophobic layer to the electrophoretic deposition layer, there is a second process comprising:

engraving the metal alloy substrate to form at least a second chamfered edge;
applying a passivation layer to the at least a second chamfered edge;
applying an electrophoretic deposition layer to the passivation layer; and
applying a hydrophobic layer to the electrophoretic deposition layer.

In some examples, a first electrophoretic deposition layer comprising a first colorant is applied to the passivation layer of the first chamfered edge, and a second electrophoretic deposition layer comprising a second colorant is applied to the passivation layer of a second chamfered edge.

The metal alloy substrate is engraved to form at least one chamfered edge. The coated metal alloy substrate may be engraved by a laser-cutting process or a Computer Numerical Control (CNC)diamond cut process. The CNC diamond cut process may use a cutting fluids including water-based cutting fluid.

The chamfered edge formed by the engraving may be an exposed non-oxidized surface of the metal alloy substrate. The non-oxidized surface of the substrate exposed in this way is an uncoated surface of the substrate that has not undergone substantial oxidation. The engraving process removes a part of the metal alloy substrate, including, for example, any oxidized layers to expose a shiny surface of the underlying substrate. In some examples, the metal alloy substrate has been pre-coated or pre-treated before the engraving process, for example, using the processes described herein. If the metal alloy substrate has been pre-coated or pre-treated, the engraving process removes a part of the coating to expose a shiny surface of the underlying substrate.

Engraving the metal alloy substrate to form at least one chamfered edge may be carried out to form a predefined pattern or shape. The engraving process may allow the formation of patterns that will provide a surface of the chamfered edge with a texture or finish that is different to the texture or finish of the metal alloy substrate that has not been engraved, in other words, the non-chamfered surface.

Engraving the metal alloy substrate to form at least one chamfered edge may be carried out using a Computer Numeric Control (CNC)diamond cutter or a laser engraver. Using this process, parts of the metal alloy substrate may be cut away and each resulting chamfered edge may form an edge, a sidewall, a logo, a gap for a click pad, a gap for a fingerprint scanner.

A passivation layer is applied to at least one chamfered edge. The passivation layer may be sprayed, rollered, dipped, or brushed onto the metal alloy surface.

An electrophoretic layer is then deposited on at least part of the passivation layer. To carry out the electrophoretic deposition, the metal alloy substrate is made an electrode of an electrochemical cell. The electrochemical cell also has an inert electrode as the counter electrode and an electrolyte comprising the electrophoretic polymer. A potential difference is applied across the electrodes of the electrochemical cell to deposit the electrophoretic polymer over the coating layer. The electrolyte may have a concentration of from about 1 wt. % to about 25 wt. %, such as from about 5 wt. % to about 20 wt. %, or from about 10 wt. % to about 15 wt. % of the electrophoretic polymer. The polymer, in general, has ionizable groups. When the polymer is a negatively charged material, then it will be deposited on the positively charged electrode (anode). When the polymer is a positively charged material, then it will be deposited on the negatively charged electrode (cathode).

In some examples, a sealing layer may be deposited on at least part of the passivation layer, before applying the electrophoretic layer. A sealing layer may be applied, for example, by dipping. A hydrophobic layer is applied to the electrophoretic deposition layer. The hydrophobic layer may be sprayed, rollered, dipped, or brushed onto the metal alloy surface.

### Pre-Treatment of Metal Alloy Substrate to Form a First Layered Surface

In some examples, the metal alloy substrate may be pre-treated to form a first layered surface before engraving the metal alloy substrate.

The first layered surface may comprise a single layer or a combination of layers. The first layered surface may comprise, an oxidized layer, an inorganic layer, a protective layer or a combination thereof.

In some examples, the metal alloy substrate may be treated with micro-arc oxidation or preliminary passivated before engraving the metal alloy substrate to form at least one chamfered edge.

In some examples, the metal alloy substrate is treated with micro-arc oxidation before applying the hydrophobic layer. Micro-arc oxidation (MAO) is an electrochemical oxidation process that can, for example, generate an oxidized layer on the metal alloy substrate.

MAO involves creating micro-discharges on a surface of the metal alloy immersed in an electrolyte to produce a crystalline oxide coating. The resulting micro-arc oxide layer may be ductile and have a relatively high hardness. Unlike anodizing processes, MAO employs a high potential such that discharges occur. The resulting plasma can modify the structure of the oxide layer. MAO is a chemical conversion process that causes oxidation of the underlying metal alloy material, instead of an oxide layer being disposed on to a surface of the metal alloy. This may lead to a metal surface with enhanced wear and corrosion resistance and may prolong the component lifetime. In comparison to an oxide layer produced by a deposition process, a micro-arc oxide layer may have a higher adhesion to the underlying metal alloy The electrolytic solution for MAO may comprise an electrolyte selected from sodium silicate, sodium phosphate, potassium fluoride, potassium hydroxide, sodium hydroxide, fluorozirconate, sodium hexametaphosphate, sodium fluoride aluminium oxide, silicon dioxide, ferric ammonium oxalate, a salt of phosphoric acid, polyethylene oxide alkylphenolic ether and a combination thereof.

The oxidised layer may have a thickness of from about 3 μm to about 15 μm, such as from about 5 μm to about 12 μm, from about 7 μm to about 10 μm. The thickness of the oxidised layer can be measured using, for example, a micrometre screw gauge or scanning electron microscope (SEM).

In some examples, the metal alloy substrate is preliminary passivated before applying a hydrophobic layer. Preliminary passivation is a process which comprises depositing an inorganic layer on the metal alloy substrate. The inorganic layer may comprise a salt selected from a molybdate salt, a vanadate salt, a phosphate salt, a chromate salt, a stannate salt and a manganese salt. In one example, the inorganic layer comprises a phosphate salt. The inorganic layer may contain oxidic salts that can provide the first surface with a dark grey appearance. In one example, the inorganic layer may be non-transparent.

The inorganic layer may have a thickness of from about 0.5 μm to about 5 μm, such as from about 1 μm to about 4 μm, or about 2 μm to about 3 μm. The thickness of the inorganic layer can be measured using, for example, a micrometre screw gauge or scanning electron microscope (SEM).

In one example, both an oxidized layer of the metallic substrate and an inorganic layer may be present. In these examples, micro-arc oxidation and preliminary passivation are carried out in a stepwise manner. In one example, the inorganic layer can be deposited or coated on the surface of the metal alloy substrate.

In one example, the oxidized layer or the inorganic layer can be a single layer. By itself, the micro-arc oxide layer or the preliminary passivation layer/inorganic layer may prevent corrosion of the metal alloy substrate.

The first layered surface may further comprise at least one protective layer, such as two, three or four protective layers. Each protective layer may be selected from a primer coating layer, a base coating layer, powder coating layer and a top coating layer. The protective layer may be deposited or coated directly on to the oxidized layer or the inorganic layer. In some examples, after depositing the protective layer, the protective layer is heated or UV-cured. In some examples, the primer coating layer, base coating layer and top coating layer may be applied to the metal alloy substrate by printing. Each of these protective layers may be made of different materials and may provide different functionality, such as heat resistance, hydrophobicity, and anti-bacterial properties.

The primer coating layer may comprise a polyurethane or a filler selected from carbon black, titanium dioxide, clay, mica, talc, barium sulfate, calcium carbonate, a synthetic pigment, a metallic powder, aluminium oxide, carbon nanotubes (CNTs), graphene, graphite, and an organic powder. The organic powder may, for example, be an acrylic, a polyurethane, a polyamide, a polyester or an epoxide. The primer coating layer may, for example, comprise a polyurethane and a filler as described above.

A heat resistant material may be included in the primer coating layer. In an example, the primer coating layer contains a heat resistant material, a filler as described above and may further comprise a polyurethane.

The primer coating layer can have a thickness of from about 5 μm to about 20 μm, such as from about 7 μm to about 18 μm, or from about 10 μm to about 15 μm.

The base coating layer may comprise polyurethane-containing pigments. The base coating layer may further comprise at least one of carbon black, titanium dioxide, clay, mica, talc, barium sulfate, calcium carbonate, synthetic pigment, metallic powder, aluminium oxide, an organic powder, an inorganic powder, graphene, graphite, plastic beads, a colour pigment or a dye. The organic powder may, for example, be an acrylic, a polyurethane, a polyamide, a polyester or an epoxide.

The base coating layer may comprise a component selected from barium sulfate, talc, a dye and a colour pigment. In one example, the base coating layer comprises a colour pigment or a dye.

The base coating layer may further comprise a heat resistant material, such as a silica aerogel. The base coating layer can comprise a heat resistant material and a component as described above.

The base coating layer can have a thickness of from about 10 μm to about 25 μm, such as from about 15 μm to about 20 μm.

By using a base coating layer, other different protective layers can easily be deposited on the first layered surface. For example, when the first layered surface has been coated with an oxide layer, the use of a base coating layer may improve adhesion between different protective layers.

The powder coating layer may comprise a polymer selected from an epoxy resin, a poly(vinyl chloride), a polyamide, a polyester, a polyurethane, an acrylic and a polyphenylene ether.

In an example, the powder coating layer is an electrostatic powder coating layer.

The powder coating layer may be electrostatically deposited or coated onto a first surface of the substrate and then the polymer may be cured.

The powder coating layer may further comprise a filler selected from carbon black, titanium dioxide, clay, mica, talc, barium sulfate, calcium carbonate, a synthetic pigment, a metallic powder, aluminium oxide, carbon nanotubes (CNTs), graphene, graphite, and an organic powder. The organic powder may, for example, be an acrylic, a polyurethane, a polyamide, a polyester or an epoxide. In one example, the fillers may be selected from talc, clay, graphene and high aspect ratio pigments.

The powder coating layer may be applied and may be cured at a temperature of about 120° C. to about 190° C.

The powder coating layer can have a thickness of from about 20 μm to about 60 μm, such as from about 30 μm to about 50 μm, or from about 35 μm to about 45 μm.

In some examples, the top coating layer is a heat-sensitive or UV-curable resin. The top coating layer may comprise at least one of a polyacrylic resin, a polyurethane resin (or polymer), a urethane acrylate resin, an acrylic acrylate resin or an epoxy acrylate resin, or a combination thereof. The top coating layer may comprise a bottom layer and a top layer coated or deposited on the bottom layer. The bottom layer may comprise a polyurethane polymer. The top layer may comprise a UV top coat. The UV top coat may, for example, be a resin, such as a polyacrylic resin, a polyurethane resin, a urethane acrylate resin, an acrylic resin or an epoxy acrylate resin. In some examples, a polyurethane polymer is found to show good adhesion with other coating layers. When the top coating layer comprises a bottom layer and a top layer, then both the bottom layer and the top layer may be transparent. The top coating layer may be transparent. The top coating layer can have a total thickness of from about 10 μm to about 25 μm, such as about 15 μm to about 20 μm.

The first layered surface may comprise multiple layers on the metal alloy substrate. In an example, the first layered surface comprises an inorganic layer, a primer coating layer, a base coating layer and a top coating layer. In an example, the first layered surface comprises an inorganic layer, a power layer, a primer coating layer, a base coating layer and a top coating layer.

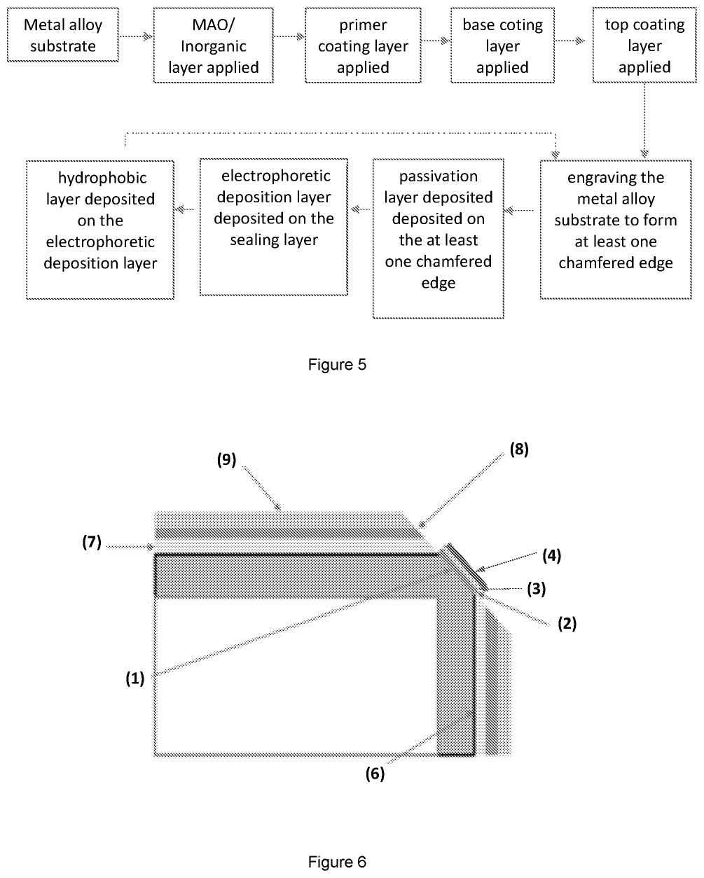

In one example, as shown in in the flow chart of FIG. 5, the metal alloy substrate is pre-treated with MAO to form an oxidised layer. In this example, a primer coat, base coat and top coat are then added in sequential layers. The metal alloy substrate is then engraved with CNC diamond cutting to form a chamfered edge. The chamfered edge is then treated with a passivation layer, an electrophoretic deposition layer and a hydrophobic layer.

### Pre-Treatment of Metal Alloy Substrate to Form a First Treated Surface

In some examples, the metal alloy substrate may be pre-treated with a cleaning treatment followed by electrophoretic deposition, to form a first treated surface, before engraving the metal alloy substrate.

The metal alloy substrate subjected with a cleaning treatment may be untreated, or may have been pre-treated with a preliminary passivation layer, an oxidized layer of the metallic substrate, or both an oxidized layer of the metallic substrate and a preliminary passivation layer.

The first treated surface may be treated with a cleaning treatment selected from degreasing, chemical polishing and deionized water cleaning. The cleaning treatment may even out the surface of the metal alloy substrate.

In one example degreasing is carried out in an ultrasonic vibration bath: comprising an alkaline cleaning process using 0.3-2.0 wt. % sodium caseinate, sodium polyacrylate, sodium polyoxyethylene alkyl ether carboxylate, and sodium dodecyl sulfate in an ultrasonic vibration degreasing bath at pH 9-13 to remove organic impurities, grease and oil from a surface.

In one example, chemical polishing is carried out using 0.1-3 wt. % acid solution selected from hydrochloric acid, nitric acid, phosphoric acid, sulfuric acid and combinations thereof.

An electrophoretic polymer may then be applied to the cleaned metal alloy substrate surface. The electrophoretic polymer layer is formed by an electrophoretic deposition (EPD) process, for example, as described herein. The electrophoretic polymer may be selected from polyacrylic polymer, polyacrylamide-acrylic copolymer and epoxy-containing polymer.

### Electronic Device

The electronic device of the present disclosure may be a computer, a laptop, a tablet, a workstation, a cell phone, a portable networking device, a portable gaming device and a portable GPS.

The electronic device has an electrical circuit, such as a motherboard or display circuitry. The housing may be external to the electrical circuit.

### Housing

As described in the present disclosure, an electronic device may have a housing. In some examples there is provided an electronic device having a housing, wherein the housing comprises:

a metal alloy substrate with at least one chamfered edge;
a passivation layer deposited on the at least one chamfered edge;
an electrophoretic deposition layer deposited on the passivation layer; and
a hydrophobic layer deposited on the electrophoretic deposition layer.

The housing comprises a metal alloy substrate disclosed herein. The metal alloy substrate can be light-weight and may provide a durable housing. The housing of the present disclosure may have cosmetic features that are visually appealing to a user, such as an attractive surface finish.

The housing may provide an exterior part of the electronic device, such as a cover or a casing of the electronic device. The housing may include a support structure for an electronic component of the electronic device. The housing may include a battery cover area, a battery door, a vent or combinations thereof.

The housing may provide a substantial part of the cover or the casing of the electronic device. The term “substantial part” in this context refers to at least about 50%, such as at least about 60%, at least about 70%, at least about 80% or at least about 90%, of the total weight of the cover or the casing. The housing may provide the entire cover or casing of the electronic device.

The housing can be a cover, such as a lid, the casing or both the cover and the casing of the electronic device. The casing may form a bottom or lower part of the cover of the electronic device. For example, the housing is the casing of a laptop, a tablet or a cell phone.

The housing may comprise a dual surface metal alloy substrate, wherein one of the surfaces is a chamfered edge. The main non-engraved surface of the metal alloy substrate may provide a bezel for a display screen, a casing, or wrist rest for a keyboard.

The chamfered edge may provide an edge or peripheral area in the housing for a touchpad, a fingerprint scanner, a trackball, a pointing stick, or a button, such as a mouse button or a keyboard button.

Examples of housings of the present disclosure are shown in FIGS. 2, 4 and 6, which are partial cross sections through the housing.

The housing shown in FIG. 2 is a partial cross-section of the housing at the chamfered edge (1). The chamfered edge (1) has a passivation layer (2) deposited thereon, an electrophoretic deposition layer (3) deposited on the passivation layer, and a hydrophobic layer (4) deposited on the electrophoretic deposition layer.

In a further example, FIG. 4 shows an example of a partial cross-section of a housing with a chamfered edge (1). The chamfered edge (1) has a passivation layer (2) deposited thereon, a sealing layer (5) deposited on the passivation layer, an electrophoretic deposition layer (3) on the sealing layer, and a hydrophobic layer (4) deposited on the electrophoretic deposition layer.

In a further example, the housing shown in FIG. 6 shows an example of a cross-section of a housing. The metal alloy substrate has been first pre-treated with an oxidised layer (6), a primer layer (7), a base coat layer (8) and a top coat layer (9) to form a first-coated surface. The pre-treated metal alloy had then been engraved to form a chamfered edge (1). The chamfered edge has a passivation layer (2) deposited thereon, an electrophoretic deposition layer (3) deposited on the passivation layer and a hydrophobic layer (4) deposited on the electrophoretic deposition layer.

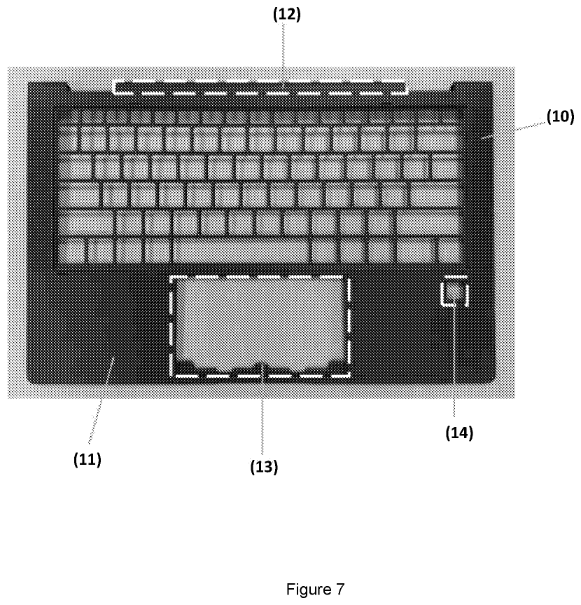

FIG. 7 shows an example of a housing of the present disclosure. The housing is a casing (10) for a keyboard of a laptop. The non-engraved coated surface of the metal alloy substrate (11) provides a wrist rest and cover for the laptop. Chamfered edges form further surfaces such as (12), (13) and (14). The chamfered edges of this housing are found to have good metallic lustre. Along with a high metallic lustre, the surfaces are also found to be corrosion resistant and have a durable coating.

### EXAMPLES

The following illustrates examples of the methods and other aspects described herein. Thus, these Examples should not be considered as limitations of the present disclosure, but are merely in place to teach how to make examples of the present disclosure.

### Example 1

A keyboard casing for a laptop was manufactured from a magnesium alloy substrate comprising the magnesium alloy AZ31 B, which comprises, based on the weight of the total alloy: Al: 2.5-3.5 wt. %, Zn: 0.6-1.4 wt. %, Mn: 0.2 wt. %, Si:0-1 wt. %, Cu: 0.05 wt. %, Ca: 0.04 wt. %, Fe: 0.005 wt. %, Ni: 0.005 wt. % and the remainder being Mg and inevitable impurities.

An oxidized surface layer was formed on the magnesium alloy substrate by micro-arc oxidation. The oxidized surface layer was then coated with a primer coating layer of polyester polyurethane. The primer coating layer was coated with a base coating layer of polyurethane and a top coating layer of urethane acrylate.

Chamfered edges were cut into the coated substrate using a CNC cutting process. This process uses a diamond cutting procedure, using a lathe, to remove a thin Mg alloy layer to expose a non-oxidised surface of the coated metal alloy substrate. This cuts an opening in the casing for a touchpad. The machine used was a Brother Speedio S500 Z1 (machine dimensions 61.4”×87.4″×98.3″). The dimensions of the touchpad were between 0.3-2 mm in width.

The exposed chamfered edge was coated with a solution comprising a chelated metal complex wherein the chelating agent is DTTPH and the metal ion is zinc. The solution was dried and formed a transparent passivation layer which comprises DTTPH and zinc. The transparent passivation layer protects the underlying metallic surface of the substrate and prevents it from undergoing atmospheric oxidation.

Using electrophoretic deposition an electrophoretic deposition layer comprising 10 wt. % polyacrylic polymer, 5 wt. % pigment yellow 191, 0.5 wt. % sodium polyacrylate, and 0.3 wt. % glutaraldehyde, based on the total weight of the electrophoretic deposition layer, was applied to the passivation layer. The substrate was then heated at 170° C. for 45 minutes.

To the electrophoretic deposition layer was applied a hydrophobic layer, by spray coating a hydrophobic fluid comprising 20 wt. % polyvinylidenefluoride (Hylar® 460), 40 wt. % isophorone, 5 wt. % cyclohexanone, and 35 wt. % paraloid B44 acrylic resin, based on the total weight of the hydrophobic fluid. The hydrophobic layer was heated to a temperature of 100° C. to cure. The hydrophobic layer had a thickness of 750 nm.

In this example, the laptop housing had a yellow-coloured touchpad.

### Example 2

A keyboard casing for a laptop was manufactured from a magnesium alloy substrate as described in Example 1.

A further chamfered edge was then cut into a second area of the coated metal alloy substrate using a CNC cutting process to expose a non-oxidised surface of the coated metal alloy substrate to cut an opening in the casing for a fingerprint scanner.

To the second chamfered edge was applied a transparent passivation layer, as described in Example 1.

Using electrophoretic deposition, a red-coloured electrophoretic layer was applied to the sealing layer. The electrophoretic deposition layer comprised 10 wt. % polyacrylic polymer, 5 wt. % Pigment Red 168 MF, 0.5 wt. % sodium polyacrylate, and 0.3 wt. % glutaraldehyde, based on the total weight of the electrophoretic deposition layer. The substrate was then heated at 170° C. for 45 minutes.

To the electrophoretic deposition layer was applied a hydrophobic layer, as described in Example 1.

The resultant substrate had two chamfered edges, both of which were coloured. The laptop housing had a part yellow-coloured touchpad and a red-coloured fingerprint scanner.

The magnesium alloy substrate of the examples exhibited an attractive metallic lustre. The coated metal alloy substrates are found to pass 2 cycles of a 96 hour salt-fog test in accordance with ASTM 117. These corrosion resistance properties were observed in all parts of the substrate including the chamfered edges. In addition, different areas of the substrate comprising chamfered edges can have different colours, which are likewise individually chosen.

Examples 1 and 2 were also carried with the additional application of a sealing layer between the passivation layer and the electrophoretic deposition layer. In these examples, the sealing layer comprises 3 wt %. of aluminium fluoride of and 0.5 wt. % of surfactant was applied to the passivation layer. The addition of a sealing layer was found to further enhance corrosion resistance, which is thought to be due to a reduction in surface activity of the exposed Mg alloy surface.

1. A coated metal alloy substrate for an electronic device, wherein the coated metal alloy substrate comprises at least one chamfered edge and comprises:
a passivation layer deposited on the at least one chamfered edge;
an electrophoretic deposition layer deposited on the passivation layer; and
a hydrophobic layer deposited on the electrophoretic deposition layer.

2. The coated metal alloy substrate according to claim 1, wherein the passivation layer is a transparent passivation layer comprising a chelating agent and a metal ion or chelated metal complex thereof.

3. The coated metal alloy substrate according to claim 2, wherein the chelating agent is selected from ethylenediaminetetraacetic acid, ethylenediamine, nitrilotriacetic acid, diethylenetriaminepenta(methylenephosphonic acid), nitrilotris(methylenephosphonic acid), 1-hydroxyethane-1,1-diphosphonic acid and phosphoric acid, and the metal ion is selected from an aluminium ion, a nickel ion, a chromium ion, a tin ion, an indium ion, and a zinc ion.

4. The coated metal alloy substrate according to claim 1, wherein the electrophoretic deposition layer comprises an electrophoretic polymer selected from polyacrylic polymer, polyacrylamide-acrylic copolymer and epoxy-containing polymer.

5. The coated metal alloy substrate according to claim 1, wherein the electrophoretic deposition layer comprises a colorant.

6. The coated metal alloy substrate according to claim 1, wherein the hydrophobic layer comprises a fluoropolymer selected from fluorinated olefin-based polymers, fluoroacrylates, fluorosilicone acrylates, fluorourethanes, perfluoropolyethers, perfluoropolyoxetanes, C1 to C6 fluorotelomers, polytetrafluoroethylene, polyvinylidenefluoride, fluorosiloxane, dodecyltrimethoxysilane, mecaptoundecyltrimethoxysilane, triethoxysilylundecanal, 11-aminoundecyltriethoxysilane and N-(2-aminoethyl)-11-undecyltrimethoxysilane.

7. The coated metal alloy substrate according to claim 1, further comprising a sealing layer deposited between the passivation layer and the electrophoretic deposition layer.

8. The coated metal alloy substrate according to claim 1, wherein the metal alloy substrate comprises a metal selected from aluminium, magnesium, lithium, titanium, niobium, zinc and alloys thereof.

9. The coated metal alloy substrate according to claim 1, wherein the metal alloy substrate is an insert moulded metal substrate comprising a plastic insert.

10. The coated metal alloy substrate according to claim 9, wherein the plastic insert comprises a plastic selected from polybutylene terephthalate, polyphenylene sufide, polyamide, polyphthalamide, acrylonitrile butadiene styrene, polyetheretherketone, polycarbonate and acrylonitrile butadiene styrene with polycarbonate.

11. A process for producing a coated metal alloy substrate for an electronic device comprising:
engraving the metal alloy substrate to form at least one chamfered edge;
applying a passivation layer to the at least one chamfered edge;
applying an electrophoretic deposition layer to the passivation layer; and
applying a hydrophobic layer to the electrophoretic deposition layer.

12. The process according to claim 11, wherein engraving the metal alloy substrate is carried out using a CNC diamond cutter or a laser engraver.

13. The process according to claim 11, wherein a first electrophoretic deposition layer comprising a first colorant is applied to part of the passivation layer, and a second electrophoretic deposition layer comprising a second colorant is applied to a further part of the passivation layer.

14. The process according to claim 11, wherein the metal alloy substrate is treated with micro-arc oxidation or preliminary passivated before engraving the metal alloy substrate to form at least one chamfered edge.

15. An electronic device having a housing, wherein the housing comprises:
a metal alloy substrate with at least one chamfered edge;
a passivation layer deposited on the at least one chamfered edge;
an electrophoretic deposition layer deposited on the passivation layer; and
a hydrophobic layer deposited on the electrophoretic deposition layer.
